(19) United States
(12) Patent Application Publication
(10) Pub. No.: US 2015/0042372 A1
(43) Pub. Date: Feb. 12, 2015

(54) Addressable test circuit and test method for key parameters of transistors

(71) Applicant: SEMITRONIX CORPORATION, Hangzhou (CN)

(72) Inventors: WEIWEI PAN, Hangzhou (CN); YONGJUN ZHENG, Hangzhou (CN)

(73) Assignee: SEMITRONIX CORPORATION, Hangzhou (CN)

(21) Appl. No.: 14/523,927

(22) Filed: Oct. 26, 2014

Related U.S. Application Data
(63) Continuation of application No. PCT/CN2013/076969, filed on Jun. 8, 2013.

(30) Foreign Application Priority Data
Nov. 28, 2012 (CN) 201210492931.9

(51) Int. Cl. G01R 31/26; H01L 21/66

(52) U.S. Cl. CPC G01R 31/2607; H01L 22/34; G01R 31/2601
USPC 324/762.01

(57) ABSTRACT

Methods of testing key parameters of transistors can be achieved using an addressable test circuit. Saturation current and leakage current of transistor are measured through different test signal lines. The addressable test circuit can be applied to a plurality of MOS transistors, each MOS transistor has a gate end G, a drain end D, a source end S, and a substrate B, wherein the S end and D end of each MOS transistor are respectively connected to different test signal lines. The test circuit can have a high area utilization rate such that it has the capacity to put a lot of transistors within one small wafer area. In addition, each transistor's I_{dsat}, I_{off} can be measured accurately.

### CROSS-REFERENCE TO RELATED APPLICATIONS

The present application is a continuation of, and claims priority to, PCT Patent Application No. PCT/CN2013/076969 filed on Jun. 8, 2013, which claims priority to Chinese Patent Application No. 201210492931.9 filed on Nov. 28, 2012. The disclosures of these applications are hereby incorporated by reference in their entirety.

### BACKGROUND

With the development of integrated circuits, the characteristic size of devices is rapidly being reduced, and the circuit performance is improved. However, process development reaching nanometer technology also brings a series of challenges, especially the problem of process volatility. The smaller feature size means smaller margin of process volatility during the manufacturing process, leading to greater instability of process parameters, such as random fluctuations of temperature, doping concentration, etc., and the key size fluctuations caused by lithography, chemical mechanical polishing (CMP), etc., these fluctuations will lead to large fluctuations of the threshold voltage and rapid increase of current leakage, they not only affect the yield of the circuit, but also affect the performance and reliability of the circuit. In this regard, on the one hand, detecting and diagnosing various effects and phenomena of device to improve the level of technology, to reduce the impact of process fluctuations; on the other hand, these effects and variability data are used in statistical modeling, thereby providing IC designers the models, therefore, in the early of design process, the designers will be able to forecast the process fluctuation and the mismatch behavior of IC performance precisely.

For MOS transistor, the key parameters need to be detected including saturation current I_{dsat}, the threshold voltage Vₜ, the subthreshold leakage current I_{off} etc. In the traditional short-range test chip, each port of the being tested MOS transistor individually connect to the probe pin (PAD). PAD occupy large area of wafer, therefore, the number of PAD is limited, resulting in the number of transistors can be measured is limited, and the area of utilization is low. So that test chips designed by this method are unable to meet the needs of MOS tube statistical modeling.

The test method of addressable test chip is as follows: add a switch circuit between each port of MOS transistor and PAD, control the on/off state of the switch circuit through addressable circuit. When a MOS transistor is selected as a DUT, turn on all switch circuits which connect with ports of the selected MOS transistor, at the same time, turn off other switching circuits, make sure the test signal access to the selected MOS transistor uniquely, show in FIG. 1. Since all MOS transistors shared a group of PAD through addressable circuits and switch circuits, the problem of measuring a large number of transistors in a limited area on wafer is solved, the test method greatly improves the test chip area utilization, therefore the design approach of test chip in advance process node applications are very broad.

Since the switch circuit are not the ideal switch, when the switch circuit in conducting state (on-state), the conduction resistance (Rₒₙ) exists. Therefore, in addressable test chip, the test signal line end is applied a specific voltage, the voltage in the port of selected MOS transistor is different with the applied voltage. This difference is particularly evident in measuring I_{dast}, the lead resistance and the conduction resistance of switch circuit produce significant voltage drop due to the flow through I_{dsat}, the greater I_{dsat}, the greater voltage will be generated, the influence in measurement can't be ignored. In order to solve this problem, a common practice is that, connect two test signal lines to D end and S end of MOS transistor respectively, one line is applied to force voltage, another signal line is to sense voltage. Detecting the voltage of D end or S end by the sense end, if it didn't meets the measurement conditions, adjusting the force voltage to eliminate the influence due to voltage drop on conduction resistance and lead resistance, show in FIG. 2. However, the greater I_{dsat} of a device under test (DUT), the greater voltage drop arose from conduction resistance of switch circuit and lead resistance, so that the force end need to force much voltage. When this voltage exceeds the bear range of switch circuit which was connected to force end directly, the switch circuit will has a breakdown, lead to the whole chip can't work properly. In view of this, in the voltage range of the switch circuit can withstand, to make the greater range of DUT's I_{dsat} can be measured, the conduction resistance of switching circuit must be smaller.

There is still a certain electric leakage when switch circuit in off state. When a large number of MOS transistors share a test signal line through switch circuits, the effect on measurement due to accumulated electric leakage of switch circuit can't be ignored, especially the impact for I_{off} and Gₗₑₐₖ. The existing method in current to measure subthreshold leakage is that, inserting a selector between working voltage or ground voltage (VDD/GND) of MOS transistor and the drain end of DUT, and said selector is comprised by PMOS. These selectors select a DUT under the control of EN signal, the selected MOS transistors connected with VDD signal line, the unselected MOS transistors connected with GND signal line. The electric leakage of selected MOS transistor is tested in VDD end, to reduce the effect on measurement which is arose from the electric leakage of unselected MOS transistors. The supply voltage of GND is equal to VDD to make sure no voltage drop between unselected MOS transistors and the source-drain end of PMOS which connect to VDD, and reduce the impact on measurement arose from electric leakage of PMOS switches. Its circuit structure is shown in FIG. 3. The shortcomings including: (1) here PMOS is thick-oxide device, the substrate voltage is larger than the force voltage VDD/GND when testing sub-threshold leakage current of DUT, so that, even if there is no electric leakage between source end and drain end, there still has voltage drop between source end and substrate, and a certain electric leakage; (2) using a PMOS as a switch circuit of D end, in order to reduce the electric leakage current of switch, the switch circuit's conduction resistance will be very large, this will effects the measurement of I_{dsat}, therefore, this kind of switch circuit will has a certain degree of compromise between measuring saturation current and leakage current.

### SUMMARY

The present disclosure relates generally to the field of the method to measure key parameters of transistor, and more specifically, to an addressable test circuit and test method for key parameters of transistors.

An addressable test circuit for testing key parameters of transistor, the addressable test circuit is applied to a plurality of MOS transistors, each MOS transistor has a gate end G, a drain end D, source end S and a substrate B, what is characterized in that, the S end or D end of each MOS transistor is connected to the first test signal line, and it also be connected to the second signal line through switch, another end, D end or S end of each MOS transistor is connected to the third test signal line directly, and to the fourth signal line through switch. Wherein, the state of all switch circuits are controlled through the selection signals which are generated by addressable circuit, and the addressable circuit is composed of combinational logic circuits.

Preferably, the S end of each MOS transistor is connected to the test signal line SF, and each of the S end also via a switch S_{SS} to connect with another test signal line SS; The D end of each MOS transistor through the switch SDF, SDL to connected with test signal line DF, DL respectively.

Preferably, switch S_{DF}, S_{DL}, S_{SS} are transmission gates or MOS transistors.

Preferably, the said switch S_{DL} is NMOS, switch S_{DF}, S_{SS} are transmission gates.

Preferably, the S end of each MOS transistor connects to test signal line SF through switch S_{SF}.

A test method of an addressable test circuit, characterized in that, selecting one of the MOS transistors as the DUT through addressable circuit, closing S_{DL} which connect to the selected MOS transistor and switch S_{DF}, S_{DL}, S_{SS} which connect to the selected MOS transistor, in the same time, unclosing all switches which connect to the unselected MOS transistor, then, measuring saturation current I_{dsat} in DF end.

Preferably, the D end of the selected MOS transistor is applied voltage connection, and the S end is induced voltage connection, forcing a voltage to D/S end, the voltage of D/S can be detected through the induced voltage end to judge whether it meets measurement conditions, if not, adjusting the applied voltage.

A test method with addressable test circuit, characterized in that, selecting one of the MOS transistor as the DUT through addressable circuit, closing switch S_{DL} which connects to the selected MOS transistor and switch SDF, SSS which connect to the unselected MOS transistors, in the same time, unclosing all other switches, measuring subthreshold leakage current I_{off} in DL end.

Preferably, the supply voltage of DF end is equal to DL end's supply voltage.

The functions of test signal lines DF, DL, SF, SS respectively include:

1) DF: The test signal line to measure I_{dsat}, for measuring I_{dsat}, forcing a corresponding voltage to D end of the selected MOS transistor, and testing the end's current; for measuring I_{off}, forcing a corresponding voltage to D end of the unselected MOS transistors.

2 DL: the test signal line to measure I_{off}, for measuring I_{off}, forcing a corresponding voltage to D end of the selected MOS transistor, and testing the end's current; for measuring I_{dsat}, sensing actual voltage of the selected MOS transistor's D end.

3 SF: the S end of each DUT connects to the test signal line, it can be used to force corresponding voltage to S end.

4 SS: the signal line can be used to sense actual voltage of the selected MOS transistor's S end.

Here switch S_{DL} is NMOS. The thick-oxide device is chose generally as switch circuit, but the substrate voltage is larger than general core device, even if there is no voltage drop between source end and drain end, there still have voltage drop between source end and substrate. The substrate's voltage of NMOS is GND, the voltage through the source end and drain end of NMOS also is GND, therefore, NMOS has less electric leakage than PMOS.

The test circuit of present invention has a high area utilization rate, so that, it has the capacity to put a lot of transistors within one little wafer area, besides, each transistor's I_{dsat}, I_{off} can be measured accurately.

### BRIEF DESCRIPTION OF THE DRAWINGS

FIG. 1 is a circuit configuration diagram in the prior art;

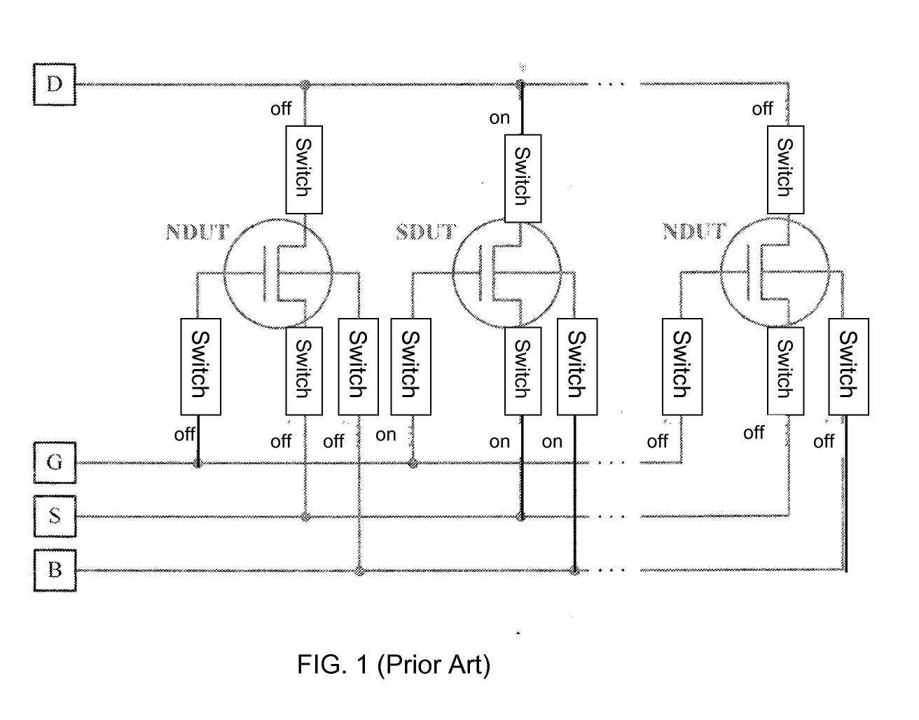

FIG. 2 is a force/sense connection structure diagram of MOS transistor's D end and S end;

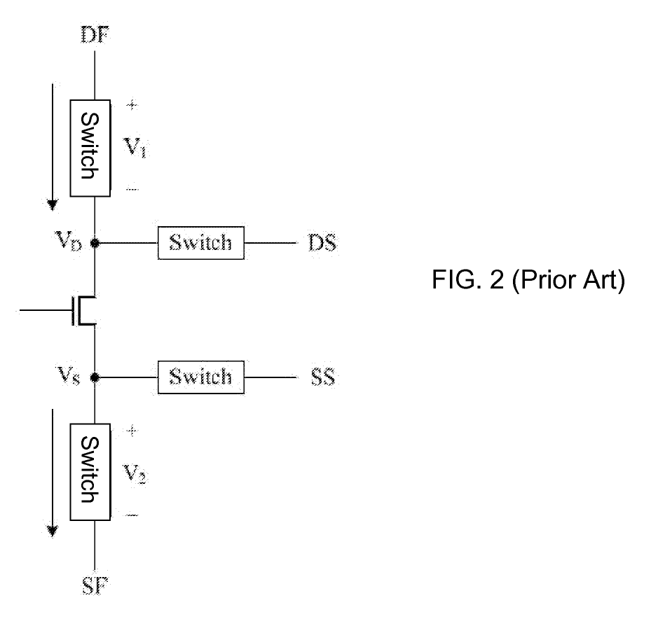

FIG. 3 is a circuit configuration diagram of another prior art;

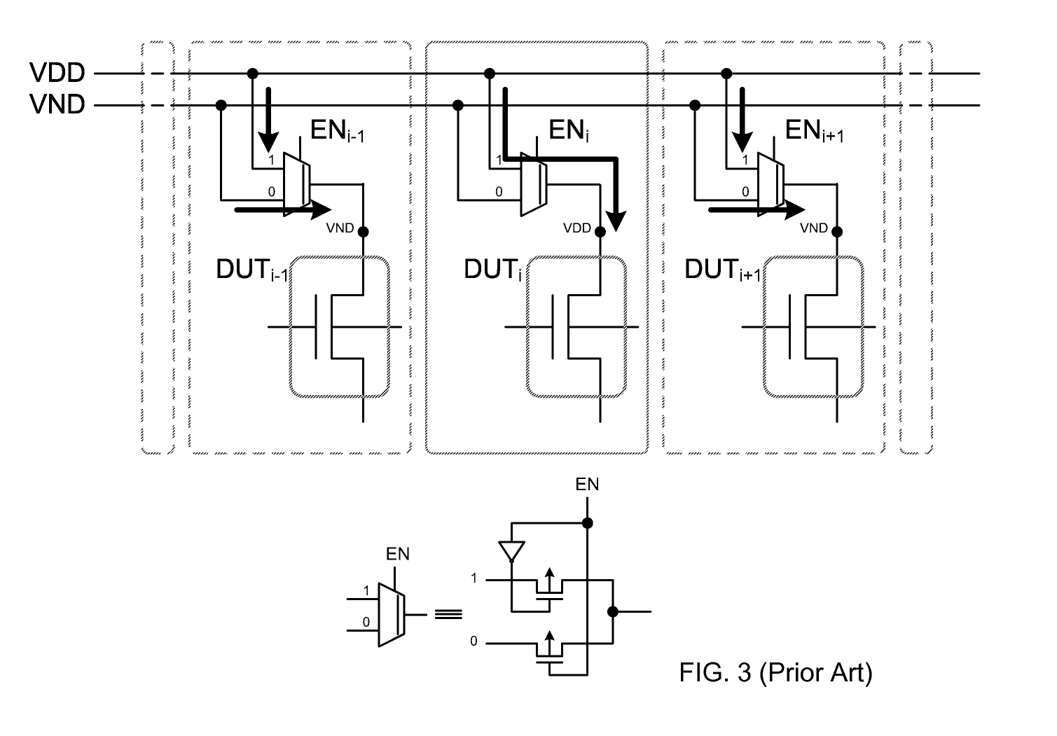

FIG. 4 is a circuit configuration diagram according to some embodiments;

FIG. 5 is a circuit configuration diagram according to some embodiments;

FIG. 6 is a circuit configuration diagram according to some embodiments.

### DETAILED DESCRIPTION

At present, there are many addressable test chips to test saturation region current of MOS transistor; however, due to MOS transistors share common test signal line through addressable circuits and switch circuits, the effect on measurement accuracy arose from accumulated background leakage current of switch circuit is very large, sub-threshold leakage current is rarely tested, and it is difficult to test sub-threshold leakage current accurately meanwhile to test saturation current accurately.

Various embodiments will be further described in conjunction with the drawings and specific embodiments, but the scope of the claimed invention is not limited thereto.

### EXAMPLE 1

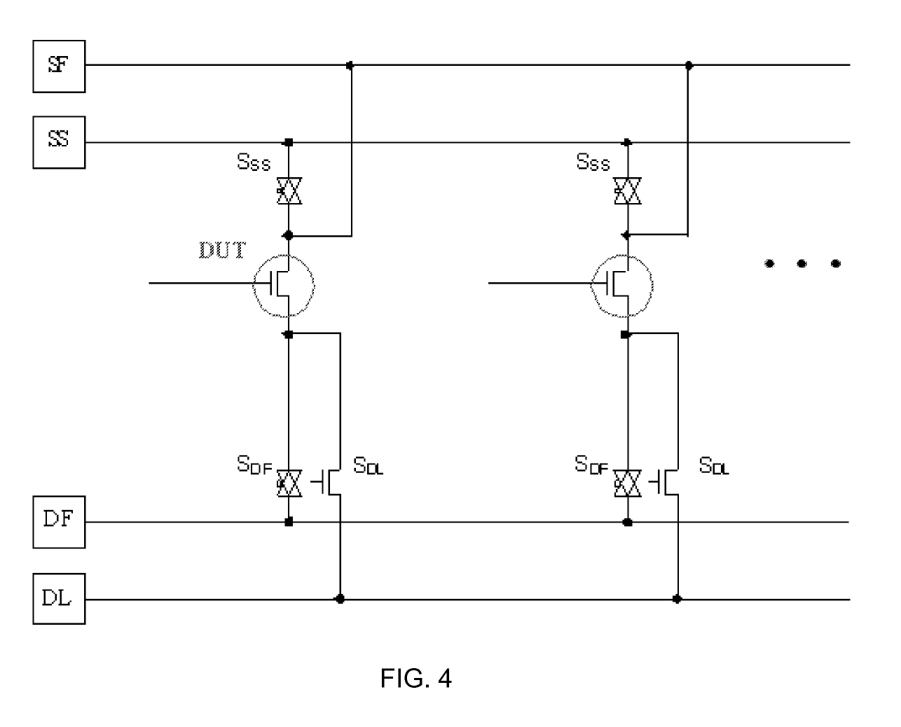

Referring to FIG. 4, an addressable test circuit used to measure key parameters of transistor is illustrated. Wherein the said addressable test circuit is applied to a plurality of MOS transistors, each MOS transistor has a gate end G, a drain end D, source end S and a substrate B, what is characterized in that, the S end of each MOS transistor connects to test signal line SF directly, at the same time, the S end of each MOS transistor connects to test signal line SS though switch S_{SS}, the D end of each MOS transistor connects to test signal line DF and DL through switch S_{DF} and S_{DL}, wherein, switch S_{DL} is NMOS, and other switches are transmission gates, the state of all switch circuits are controlled through the selection signals which are generated by addressable circuit, and the addressable circuit is composed of combinational logic circuits.

A test method of an addressable test circuit for measuring the key parameters of MOS transistor, characterized in that, selecting one of the MOS transistors as the DUT through addressable circuit, and measuring its I_{dsat} and I_{off} respectively. (in the present invention, the selected DUT by addressable circuit is abbreviated as SDUT, the unselected DUT is abbreviated as NDUT)

For measuring saturation current I_{dsat}, closing switch S_{DF}, S_{DL}, S_{SS} which connect to SDUT, in the same time, unclosing all switches which are connect to NDUT, the D end of the selected MOS transistor is applied voltage connection, and the S end is induced voltage connection, and DF,SF belong to force end, FL,SS belong to sense end, giving a voltage to force end, at the same time, the voltage of D/S end can be detected through the sense end to judge whether it meets the measurement conditions, if not, adjusting the applied voltage, measuring the saturation current I_{dsat} in DF end. Within the voltage range which the switch circuit can withstand, to make the greater range of DUT's I_{dsat} can be measured, the conduction resistance of switch circuits must be smaller. All DUT's S ends are connected to the signal line SF directly without switches' conduction resistance, and the connection resistance is very small, the switch in DF end is transmission gate, its conduction resistance is very small too, and the conduction resistance can be smaller through adjusting the size of transmission gate. So that, the range of DUT's I_{dsat} is very large, in addition, the transmission gate's resistance is a constant when the transmission gate accord with a certain size ratio, this character is very useful in measurement, the compensating voltage can be obtained through calculating, therefore, the testing speed will be accelerated.

For measuring subthreshold leakage current I_{off}, closing switch S_{DL} which connect to the selected MOS transistor and switch S_{DF}, S_{SS} which are connected to unselected MOS transistors, in the same time, unclosing all other switches, connecting the selected MOS transistor's D end to signal line DL, and the unselected MOS transistors' D end to signal line DF, this will reduce the effect on measurement caused by unselected MOS transistors' current leakage; at the same time, the supply voltage of DF end is equal to DL end's supply voltage, to make sure the both sides of switch S_{DL} which connect to signal line DL of unselected MOS transistors have no voltage drop, and reduce the effect on measurement caused by switch current leakage, the subthreshold leakage current I_{off} is measured in DL end. I_{off} and I_{dsat} are measured in different signal lines, switch S_{DL} can reduce electric leakage caused by itself trough adjusting its own size, so that, the increase of conduction resistance has no effection to measure I_{dsat}, wherein, switch S_{DL} is NMOS. The thick-oxide device is chose generally as switch circuit, but the substrate voltage is larger than general core device, even if there is no voltage drop between source end and drain end, there still has voltage drop between source end and substrate. The substrate's voltage of NMOS is GND, the voltage through the source end and drain end of NMOS also is GND, therefore, NMOS has less current leakage than PMOS.

Saturation current I_{dsat} and subthreshold leakage current I_{off} are two important parameters to judge MOS transistors' characters in nanometer process.

The measurement conditions of saturation current I_{dsat} and subthreshold leakage current I_{off} of NMOS and PMOS as shown in table 1.

G/D/S/B respectively represent MOS transistor's Gate, Drain, Source and substrate; VDD is working voltage of the MOS transistor; GND is voltage of ground, generally is 0V; W, L respectively is the width and length of channel; I₀ is a constant depend to the process level of foundry.

TABLE 1

| | NMOS | PMOS |
|---|---|---|
| I_{dast} | V_{G} = V_{D} = VDD, | V_{G} = V_{D} = GND, |
| | V_{S} = V_{B} = GND | V_{S} = V_{B} = VDD, |
| | Current of D end | Current of D end |
| I_{off} | V_{D} = VDD, | V_{D} = GND, |
| | V_{G} = V_{S} = V_{B} = GND, | V_{G} = V_{S} = V_{B} = VDD, |
| | Current of D end | Current of D end |

### EXAMPLE 2

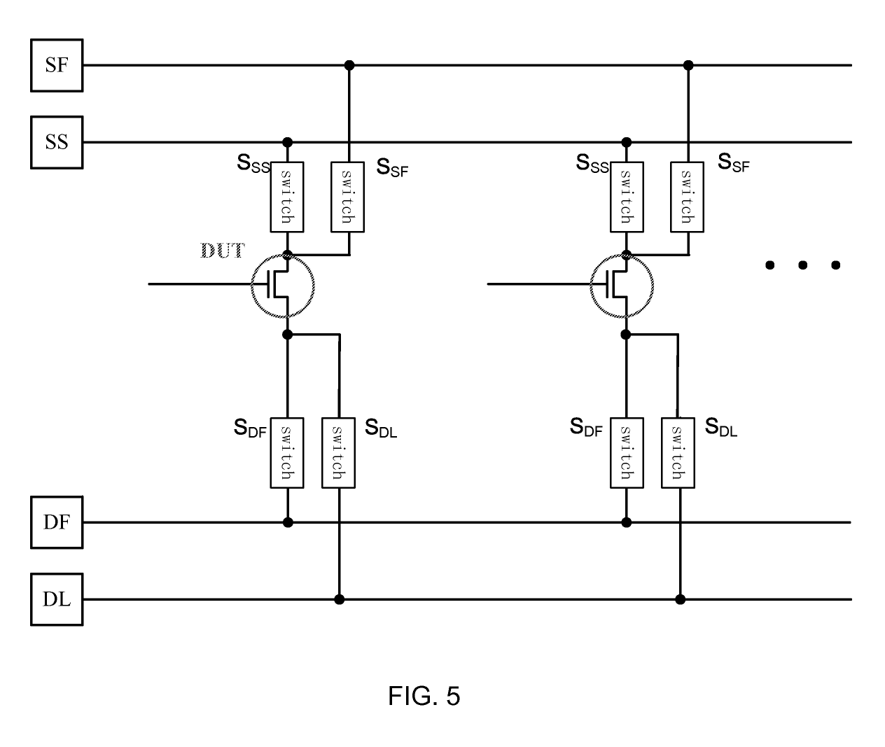

Referring to FIG. 5, the S end of each MOS transistor connects to test signal line SF through switch S_{SF}, by contrast, the S end of each MOS transistor connect to test signal line SF directly.

The working principle of present embodiment as following: similar to Example 1, selecting one of the MOS transistors as the DUT through addressable circuit, and measuring its I_{dsat} and I_{off} respectively.

For measuring saturation current I_{dsat}, closing switch S_{DF}, S_{DL}, S_{SS}, S_{SF} which connect to SDUT, at the same time, unclosing S_{DF}, S_{DL}, S_{SS}, S_{SF} which connect to NDUT, the D end of the selected MOS transistor is applied voltage connection, the S end is induced voltage connection, and DF, SF belong to force end, DL, SS belong to sense end, giving a voltage to force end, at the same time, the voltage of D/S end can be detected through the sense end to judge whether it meets the measurement conditions, if not, adjusting the applied voltage to eliminate bad effects on the measurement, the effects are arose from the drop voltage of conduction resistance and line resistance, the saturation current I_{dsat} is measured in DF end.

For measuring subthreshold leakage current I_{off}, closing switch S_{DL},S_{SF} which connect to the selected MOS transistor and switch S_{DF}, S_{SS} which are connected to unselected MOS transistors, in the same time, unclosing S_{DF}, S_{SS} which connect to the selected MOS transistor and switch S_{DL}, S_{SF} which are connected to unselected MOS transistors, connecting the selected MOS transistor's D end to signal line DL, and the unselected MOS transistors' D end to signal line DF, this will reduce the effect on measurement caused by unselected MOS transistors' electric leakage; at the same time, the supply voltage of DF end is equal to DL end's supply voltage, to make sure the both sides of switch S_{DL} which connect to signal line DL of unselected MOS transistor have no voltage drop, and reduce the effect caused by switch electric leakage on measurement, the subthreshold leakage current I_{off} is measured in DL end.

Switch S_{SF}, like other switches, can use a transmission gate or a single MOS transistor.

### EXAMPLE 3

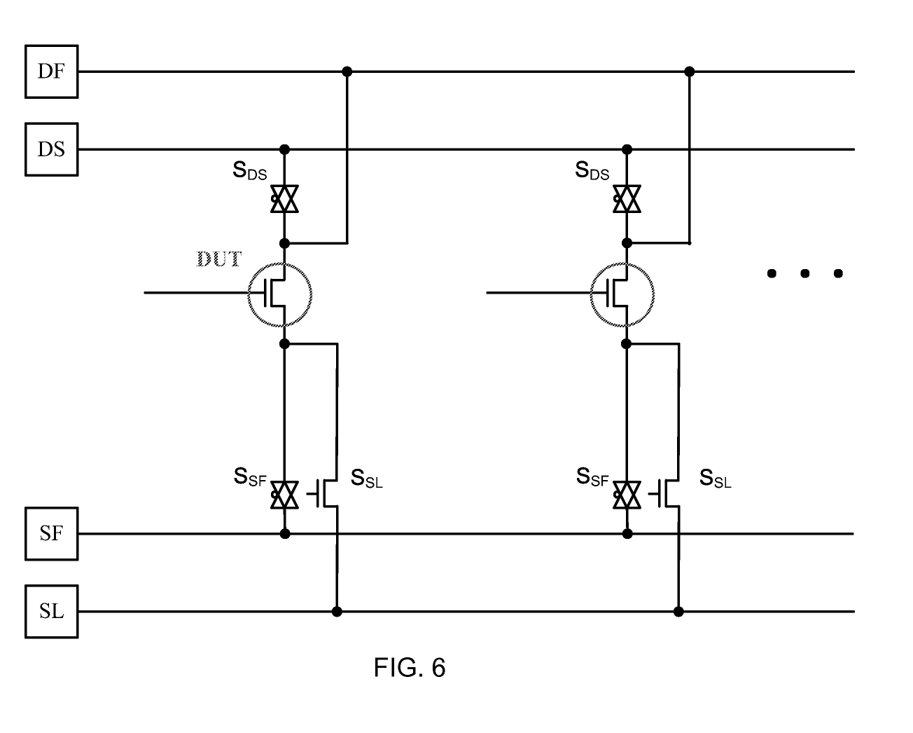

Referring to FIG. 6, different from Example 1, the D end of each MOS transistor connects to test signal line DF directly, at the same time, the D end of each MOS transistor connects to test signal line DS though switch S_{DS}; the S end of each MOS transistor connects to test signal line SF and SL through switch S_{SF} and S_{SL} respectively.

The working principle of present example as following: similar to Example 1, selecting one of the MOS transistors as the DUT through addressable circuit, and measure its I_{dsat} and I_{off} respectively.

For measuring saturation current I_{dsat}, closing switch S_{SL}, S_{DS} which connect to SDUT, at the same time, unclosing S_{SF}, S_{SL}, S_{DS} which connect to NDUT, the D end of the selected MOS transistor is applied voltage connection, the S end is induced voltage connection, and DF, SF belong to force end, SL, DS belong to sense end, giving a voltage to force end, at the same time, the voltage of D/S end can be detected through the sense end to judge whether it meets the measurement conditions, if not, adjusting the applied voltage to eliminate bad effects on the measurement, the said effects are arose from the drop voltage of conduction resistance and line resistance. The saturation current I_{dsat} is measured in DF end.

For measuring subthreshold leakage current I_{off}, closing switch S_{SL} which connects to the selected MOS transistor and switch S_{SF}, S_{DS} which are connected to unselected MOS transistors, in the same time, unclosing S_{SF},S_{DS} which connect to the selected MOS transistor and switch S_{SL} which connects to unselected MOS transistor, connecting the selected MOS transistor's S end to signal line SL, and the unselected MOS transistors' S end to signal line SF, this will reduce the effect on measurement caused by unselected MOS transistors' electric leakage; at the same time, the supply voltage of SF end is equal to SL end's supply voltage, to make sure the both sides of switch S_{SL} of unselected MOS transistor which connect to signal line SL have no voltage drop, and reduce the effect on measurement caused by switch electric leakage. The subthreshold leakage current I_{off} is measured in DL end.

1. A test method for testing a plurality of transistors, the method comprising: measuring a saturation current and a leakage current of a transistor respectively through different test signal lines.

2. An addressable test circuit configured to measure key parameters of a transistor, said addressable test circuit applicable to a plurality of MOS transistors, each MOS transistor having a gate end G, a drain end D, a source end S, and a substrate B, where the S end and the D end of each MOS transistor are respectively connected to different test signal lines.

3. The addressable test circuit of claim 2, wherein one of the S end or the D end of each MOS transistor is connected to a first test signal line, and is also connected to a second signal line through a switch; another one of the S end or the D end of each MOS transistor is connected to a third test signal line and a fourth signal line through another switch; wherein, a state of all switches are controlled through selection signals generated by an addressable circuit comprising combinational logic circuits.

4. The addressable test circuit of claim 3, wherein the S end of each MOS transistor is connected to a test signal line SF, and via a switch S_{SS} connected another test signal line SS; the D end of each MOS transistor, through switches S_{DF}, S_{DL}, is connected to test signal lines DF, DL, respectively.

5. The addressable test circuit of claim 4, wherein the switch S_{DF}, S_{DL}, S_{SS} are transmission gates or individual MOS transistors.

6. The addressable test circuit of claim 5, wherein the switch S_{DL} comprises an NMOS, and wherein the switches S_{DF}, S_{SS} are transmission gates.

7. The addressable test circuit of claim 4, wherein the S end of each MOS transistor is connected to the test signal line SF through the switch S_{SF}.

8. A test method of the addressable test circuit according to claim 4, comprising: selecting one of the MOS transistors as a DUT through the addressable circuit; closing the switches S_{DF}, S_{DL}, S_{SS} connected to the selected MOS transistor; opening all switches connected to the unselected MOS transistors, and measuring a saturation current I_{dsat} in a DF terminal.

9. The test method of claim 8, wherein the D end and the S end of the selected MOS transistor form an applied or an induced voltage coupling, the method comprising: while applying the voltage, measuring a voltage of the D end or the S end through the induced voltage, determining whether the measured voltage meets measurement conditions and accordingly adjusting the applied voltage.

10. A test method with the addressable test circuit of claim 4, comprising: selecting one of the MOS transistor as a DUT through the addressable circuit, closing the switch S_{DL} connected to the selected MOS transistor and the switches S_{DF}, S_{SS} connected to the unselected MOS transistors, while opening all other switches, equalizing a source voltage at DF and DL terminals, and measuring a subthreshold leakage current I_{off} at a DL terminal.
